(19) United States
(12) Patent Application Publication
(10) Pub. No.: US 2001/0023126 A1
(43) Pub. Date: Sep. 20, 2001

(54) Method for manufacturing interlayer dielectric layer in semiconductor device

(76) Inventor: Sun-OO Kim, Ichon-shi (KR)

Correspondence Address: Finnegan, Henderson, Farabow, Garrett & Dunner, L.L.P., 1300 I Street, N.W., Washington, DC, 20005-3315, US

(21) Appl. No.: 09/739,743

(22) Filed: Dec. 20, 2000

(30) Foreign Application Priority Data
Dec. 24, 1999 (KR) 1999-61786

(51) Int. Cl. H01L 21/4763; H01L 21/31; H01L 21/469

(52) U.S. Cl. 438/623; 438/790

(57) ABSTRACT

A method for manufacturing an interlayer dielectric layer begins with a preparation of an active matrix provided with a substrate and interconnections formed on the substrate and then the prepared active matrix is set on a chamber. Thereafter, a silicon source material, e.g., a tetra-ethyl-ortho-silicate (TEOS) or modified TEOS and a hydrogen peroxide (H₂O₂) in a gaseous state are sprayed on the active matrix. And finally, the interlayer dielectric layer is formed on the active matrix by a condensation reaction of the silicon source material and the H₂O₂.

### FIELD OF THE INVENTION

The present invention relates to a semiconductor device; and, more particularly, to method for manufacturing an interlayer dielectric (ILD) layer with an enhanced gap-fill capability using a tetra-ethyl-ortho-silicate (TEOS) and a hydrogen peroxide (H₂O₂) as a source material.

### DESCRIPTION OF THE PRIOR ART

As is well known, a semiconductor memory device has a higher degree of integration mainly by down-sizing through micronization. However, there is still a demand for downsizing the area of the memory cell.

To meet the demand, therefore, there have been proposed several methods, such as a trench type or a stack type capacitor, which is arranged three-dimensionally in a memory device to reduce the cell area available to the capacitor.

In employment of this structure of a capacitor, however, a high topological difference is produced between a memory cell region and a peripheral circuit region. Thus, the three-dimensional structure for the high degree of the integration causes a bad gap-fill capability and a step coverage when forming various layers, e.g., interlayer dielectric (ILD) layer, on a semiconductor substrate. Therefore, in a deposition of the interlayer dielectric layer, there are problems of the bad gap-fill capability and the step coverage, whereby a void may exist in the interlayer dielectric layer after the deposition.

Referring FIGS. 1A to 1E, there are shown cross sectional views setting forth a conventional method for manufacturing a semiconductor device incorporated therein the ILD layer.

The manufacturing steps begin with a preparation of a semiconductor device 110 of which predetermined manufacturing steps has been carried out in advance. And then, conductive layers are formed on the semiconductor substrate 110 and patterned into a first predetermined configuration, thereby forming interconnections 120. Thereafter, an ILD layer 130 is formed on entire surface, wherein a thickness of the interlayer dielectric layer 130 is higher than heights of the interconnections 120 as shown in FIG. 1A. Here, a distance between each interconnection 120 is narrow and the height of the interconnections 120 is high so that an aspect ratio increases. Thus, a gap-fill capability is deteriorated in depositing the ILD layer 130 so that there is a void 115 remaining in the ILD layer 130.

The conventional method for forming the ILD layer 130 is illustrated in more detail hereunder.

To begin with, after reacting tetra-ethyl-ortho-silicate (TEOS) with active oxygen such as O₃, O₂ and N₂O, the TEOS and the active oxygen are deposited on the substrate 110, thereby forming the ILD layer 130. Thereafter, the ILD layer 130 is annealed above 800° C. for densification.

In a next step as shown in FIG. 1B, a top surface of the ILD layer 130 is flattened by using a chemical mechanical polishing (CMP) process, wherein a flattened top surface of the ILD layer 130 is also higher than those of the interconnections 120. Subsequently, a photoresist layer 140 is formed on the flattened top surface of the ILD layer 130.

In an ensuing step as shown in FIG. 1C, the photoresist layer 140 is patterned into a second predetermined configuration by using a method such as a photolithography, thereby obtaining photoresist patterns 140A.

In a subsequent step, the interlayer dielectric layer 130 is patterned into the second predetermined configuration using the photoresist pattern 140A as a mask, thereby obtaining a contact hole 135. Here, while patterning the ILD layer 120 by an etching step, a polymer is accumulated in the void 115 so that the polymer in the void 115 plays a role as an etching barrier, whereby a residue 125 of an oxide remains between the void 115 and the semiconductor substrate 110 as shown in FIG. 1D.

Finally, the photoresist patterns 140A are stripped off so that whole the manufacturing steps are completed as shown in FIG. 1E, wherein the residue 125 of the oxide remains still on the substrate 110.

In the conventional method for forming the ILD layer, there may be a void therein so that the residue 125 of the oxide may remain after the etching step. Thus, the residue 125 causes the device to fail eventually. Furthermore, since the annealing process for densification is carried out at a high temperature, i.e., above 800° C., the other layers such as a metal silicide, silicide, a metal nitride, or the like, is deteriorated during the annealing process. To overcome this problem, another method for forming the ILD layer using SiH₄ and H₂O₂ is developed. However, this method also has a problem of bad reproducibility because it is carried out at approximately 0° C. In addition, it may cause a crack due to an unstable deposition layer after the annealing process.

### SUMMARY OF THE INVENTION

It is, therefore, an object of the present invention to provide method for manufacturing an interlayer dielectric (ILD) layer with a good gap-fill capability by using a tetraethyl-ortho-silicate (TEOS) or modified TEOS and H₂O₂ as a source material.

In accordance with one aspect of the present invention, there is provided a method for manufacturing an interlayer dielectric layer, the method comprising the steps of: a) setting an active matrix provided with a substrate and interconnections formed on the substrate in a chamber; b) spraying a silicon source material and a hydrogen peroxide (H₂O₂) in a gaseous state on the active matrix; and c) forming the interlayer dielectric layer on the active matrix by a condensation reaction of the silicon source material and the H₂O₂.

### BRIEF DESCRIPTION OF THE DRAWINGS

The above and other objects and features of the present invention will become apparent from the following description of the preferred embodiments given in conjunction with the accompanying drawings, in which:

FIGS. 1A, 1B, 1C, 1D and 1E are schematic cross sectional views setting forth a conventional method for manufacturing a semiconductor device incorporated therein an interlayer dielectric (ILD) layer;

FIGS. 2A, 2B, 2C, 2D and 2E are schematic cross sectional views setting forth a method for manufacturing a semiconductor device incorporated therein an interlayer dielectric (ILD) layer in accordance with a preferred embodiment of the present invention; and

FIG. 3 is a schematic view of an apparatus for forming an ILD layer.

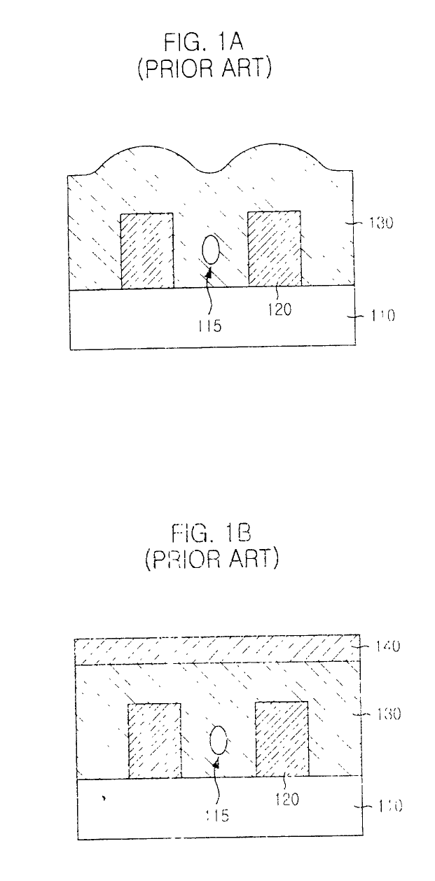

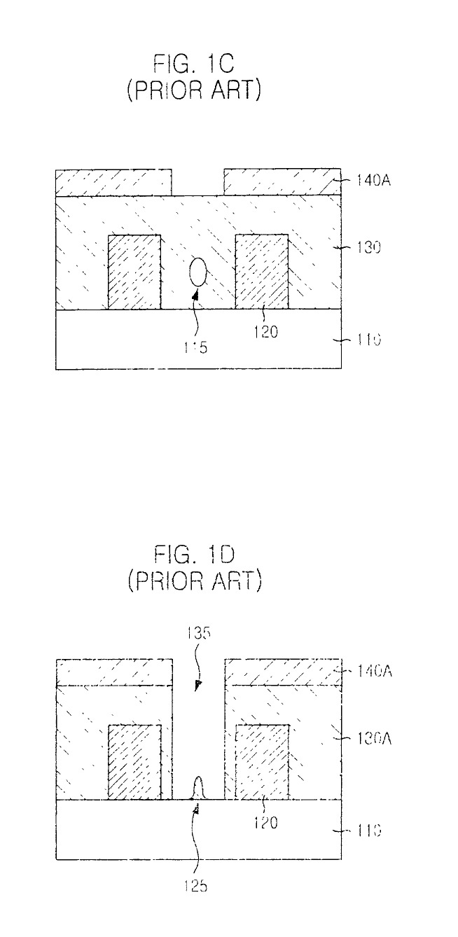

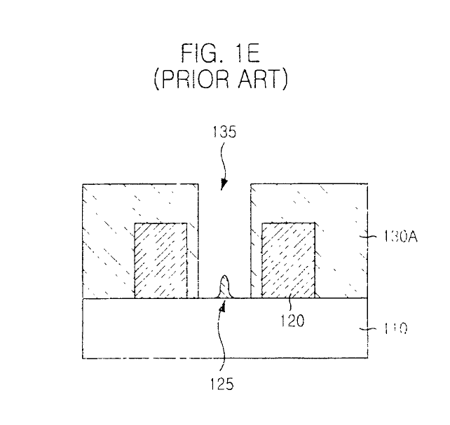

### DETAILED DESCRIPTION OF THE PREFERRED EMBODIMENTS

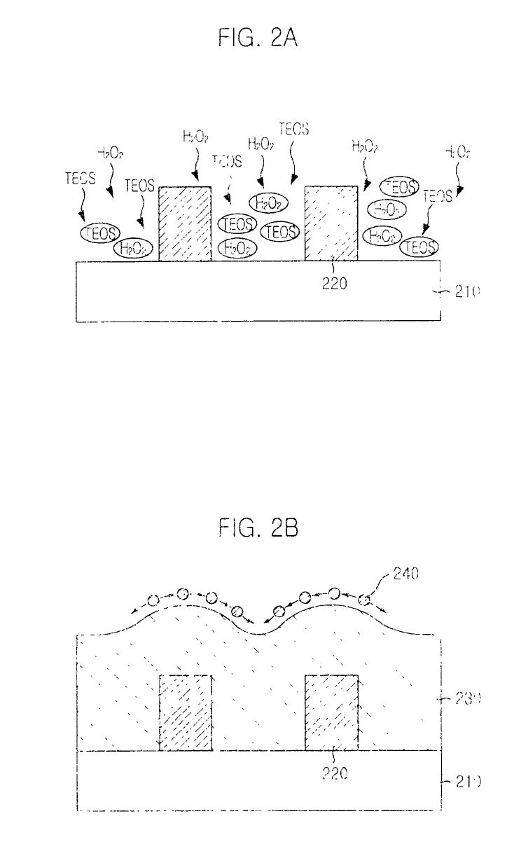

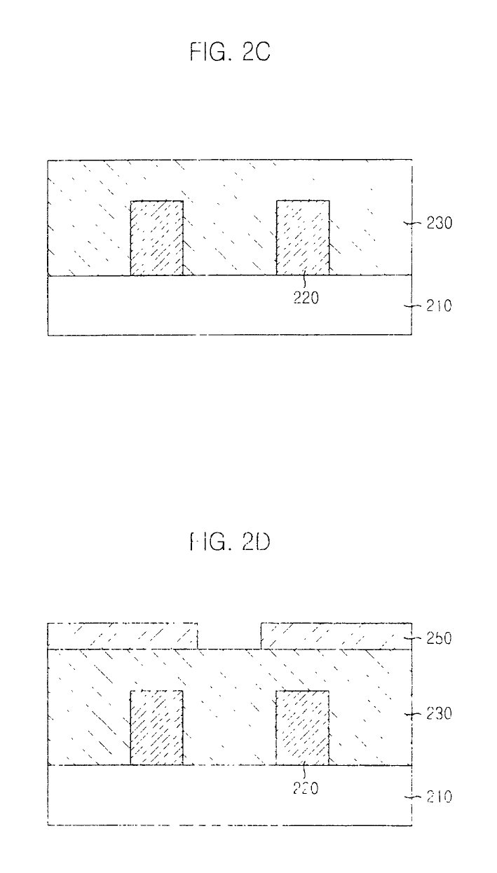

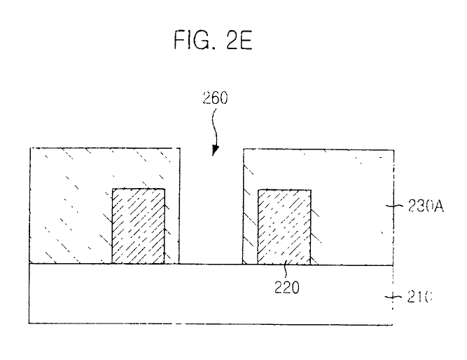

There are provided in FIGS. 2A to 2E cross sectional views setting forth a method for manufacturing a semiconductor device incorporated therein an interlayer dielectric layer (ILD) in accordance with a preferred embodiment of the present invention.

The manufacturing steps begin with a preparation of a semiconductor device 210 of which predetermined manufacturing steps has been carried out in advance. And then, conductive layers are formed on the semiconductor substrate 210 and patterned into a first predetermined configuration, thereby forming interconnections 220. Thereafter, an ILD layer 230 is formed on entire surface using a tetra-ethyl-ortho-silicate (TEOS) and a hydrogen peroxide (H₂O₂) as a source material, 10 wherein a thickness of the ILD layer 230 is higher than heights of the interconnections 220.

The process for forming the ILD layer 230 is illustrated in more detail hereunder.

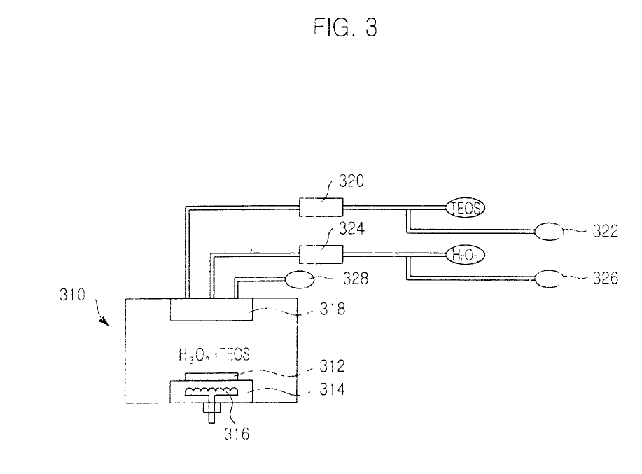

Referring to FIG. 3, there is provided a schematic view of an apparatus for forming the ILD layer 230. To begin with, a wafer 312 is set on a susceptor 314 in a chamber 310, wherein a temperature controller 316 is attached to the susceptor 314 for modulating a deposition temperature. Thereafter, a source material, e.g., TEOS and H₂O₂, is supplied into the chamber 310 through a each flow rate controller (F/C) 320, 324, wherein the TEOS and H₂O₂ are maintained in liquid state by employing a method such as a ultrasonic spray, vacuum vaporization or the like. Subsequently, the TEOS and H₂O₂ are deposited on the wafer 312 through a distributor 318. When the TEOS and H₂O₂ are supplied into the flow rate controllers 320, 324, inert gas, e.g., Ar, He, Ne or the like, is supplied from supplying devices 322, 326 simultaneously. Meanwhile, when the TEOS and the H₂O₂ in a gaseous state are supplied into the chamber 310, inert gas is supplied simultaneously from an auxiliary supplying device 328 to enhance uniformity in the chamber 310. It is preferable that the temperature and the pressure in the chamber range from approximately −20° C. to approximately 600° C. and approximately 1 Torr to approximately 2 Torr, respectively.

Referring back to FIG. 2B, there is shown a state after a deposition step progresses for a predetermined time. In this figure, the ILD layer 230 is successfully formed between the interconnections 220 without a void. In more detail, the TEOS and H₂O₂ in the gaseous state, which are supplied into the chamber 310 through the distributor 318, react with each other on a surface of the wafer 310. Therefore, a chemical structure of the TEOS, i.e., (C₂H₅O)—Si—(OH₅C₂), is changed into (C₂H₅O)—Si—O by means of active oxygen ions separated from the H₂O₂. Especially, Si—O bond or Si—OH bond produced from the above reaction, has a characteristic that they are easily bonded with each other so that —O—Si—O— bond is formed by a condensation reaction. From the condensation reaction, by-product of H₂O plays an important role in inhibiting the violent reaction with the TEOS and the H₂O₂. And further, an intermediate material 240 such as (C₂H₅O)—Si—O and (C₂H₅O)—Si—OH, has a high fluidity, thereby obtaining a good gap-fill capability.

In a next step as shown in FIG. 2C, a top surface of the ILD layer 230 is flattened by using a chemical mechanical polishing (CMP) process, wherein a flattened top surface of the ILD layer 230 is also higher than those of the interconnections 220.

In an ensuing step as shown in FIG. 2D, a photoresist layer is formed on the flattened top surface of the interlayer dielectric layer 230 and patterned into a second predetermined configuration by using a method such as a photolithography, thereby obtaining photoresist patterns 250.

In a subsequent step, the ILD layer 230 is patterned into the second predetermined configuration using the photoresist pattern 250 as a mask, thereby obtaining a contact hole 260. Here, in patterning the ILD layer 230 by an etching step, there is not any etching barrier in comparison with a prior art. Finally, the photoresist patterns 250 are stripped off so that whole the manufacturing steps are completed as shown in FIG. 2E.

In the present invention, the TEOS and the H₂O₂ are used for depositing the ILD layer, but it is possible to add an impurity material such as boron (B), phosphor (P), B and P or the like, to the source material of the TEOS and the H₂O₂. That is, in case of using TEB, TMB or TEB/TMB as a boron dopant, phosphor dopant or B/P-dopant respectively, the ILD layer becomes BSG, PSG or BPSG, respectively.

Moreover, the TEOS may be substituted by a modified TEOS which one of four C₂H₅OH groups in the TEOS is substituted by a group of CH₃ or F. In case of using the modified TEOS instead of the TEOS, the interlayer dielectric layer becomes a low dielectric silicon oxide like (SiOx(CH₃)y) or (SiOₓF_{y}).

In comparison with the prior art, the present invention provides a method for manufacturing the ILD layer with a good gap-fill capability. Additionally, the present invention has an advantage that the ILD layer can be formed without a post thermal treatment at above 800° C.

While the present invention has been described with respect to the particular embodiments, it will be apparent to those skilled in the art that various changes and modifications may be made without departing from the scope of the invention as defined in the following claims.

What is claimed is:

1. A method for forming an interlayer dielectric layer, comprising the steps of:
a) providing an active matrix on a substrate in a chamber;
b) spraying a silicon source material and a hydrogen peroxide (H₂O₂) in a gaseous state on the active matrix; and
c) forming an interlayer dielectric layer on the active matrix by condensation reaction of the silicon source material and hydrogen peroxide (H₂O₂).

2. The method as recited in claim 1, wherein the silicon source material includes a tetra-ethyl-ortho-silicate (TEOS).

3. The method as recited in claim 1, wherein the silicon source material includes a modified tetra-ethyl-ortho-silicate (TEOS).

4. The method as recited in claim 1, wherein the step of spraying a silicon source material includes supplying simultaneously an inert gas when the silicon source material and the hydrogen peroxide (H₂O₂)are supplied into a flow rate controller.

5. The method as recited in claim 1, wherein the step of spraying a silicon source material includes supplying simultaneously an inert gas when the silicon source material and the hydrogen peroxide (H₂O₂) are supplied into a distributor in the chamber.

6. The method as recited in claim 2, wherein the step of forming an interlayer dielectric layer includes adding to the hydrogen peroxide (H₂O₂) and tetra-ethyl-ortho-silicate (TEOS) one or more of boron (B) and phosphor (P).

7. The method as recited in claim 1, wherein the step of providing an active matrix includes carrying it out at a temperature and a pressure in the chamber ranging from approximately −20° C. to approximately 600° C. and approximately 1 Torr to approximately 2 Torr, respectively.
